(19) United States
(12) Patent Application Publication
(10) Pub. No.: US 2024/0422896 A1
(43) Pub. Date: Dec. 19, 2024

(54) CIRCUIT BOARD AND METHOD OF FABRICATING CIRCUIT BOARD

(71) Applicant: SAMSUNG ELECTRO-MECHANICS CO., LTD., Suwon-si (KR)

(72) Inventors: Chulmun Kang, Suwon-si (KR); Bongbu Jung, Suwon-si (KR); Ho-Jae Lee, Suwon-si (KR); Byeonggu Kang, Suwon-si (KR)

(73) Assignee: SAMSUNG ELECTRO-MECHANICS CO., LTD., Suwon-si (KR)

(21) Appl. No.: 18/639,363

(22) Filed: Apr. 18, 2024

(30) Foreign Application Priority Data
Jun. 13, 2023 (KR) 10-2023-0075632

(51) Int. Cl. H05K 1/02; H05K 1/11; H05K 3/40

(52) U.S. Cl. CPC H05K 1/0271; H05K 1/111; H05K 3/4038; H05K 2201/0209; H05K 2201/068; H05K 2201/09036; H05K 2201/09136; H05K 2203/0221; H05K 2203/107

(57) ABSTRACT

A disclosed circuit board includes an insulating core layer that has a first surface and a second surface opposing each other, an insulating auxiliary member of which at least a part is disposed in the insulating core layer and which has a coefficient of thermal expansion (CTE) different from that of the insulating core layer, a first substrate portion that includes a first insulating layer which is disposed on the first surface, and a first circuit wiring which is embedded in the first insulating layer, and a second substrate portion that includes a second insulating layer which is disposed on the second surface, and a second circuit wiring which is embedded in the second insulating layer.

### CROSS-REFERENCE TO RELATED APPLICATION

This application claims priority to and the benefit of Korean Patent Application No. 10-2023-0075632 filed in the Korean Intellectual Property Office on Jun. 13, 2023, the entire contents of which are incorporated herein by reference.

### TECHNICAL FIELD

This disclosure relates to a circuit board and a method of fabricating the circuit board.

### BACKGROUND

As the performance of electronic devices has been improved with the development of the electronics industry, semiconductor packages have been required to be densified while being miniaturized and thinned. In order to densify packages, the number of ICs required to be mounted has increased. Further, in order to realize many functions with circuit boards limited in size, the ball pitches of ICs have been gradually decreased.

As the technologies for realizing many functions with circuit boards limited in size as mentioned above have been developed, the risk of a reduction in yield due to warpage during product fabrication has increased. For this reason, it has become increasingly important to develop technologies for reducing such warpage.

### SUMMARY

At least one of embodiments attempts to provide a circuit board and a method of fabricating the circuit board capable of reducing the risk of warpage.

However, problems that the embodiments are to solve are not limited to the above-described object, and can be variously expanded within the scope of technical spirits included in the embodiments.

An embodiment provides a circuit board including an insulating core layer that has a first surface and a second surface opposing each other, an insulating auxiliary member of which at least a parts is disposed in the insulating core layer and which have a coefficient of thermal expansion (CTE) different from that of the insulating core layer, a first substrate portion that includes a first insulating layer which is disposed on the first surface, and a first circuit wiring which is embedded in the first insulating layer, and a second substrate portion that includes a second insulating layer which is disposed on the second surface, and a second circuit wiring which is embedded in the second insulating layer.

The insulating auxiliary member may have the CTE higher than that of the insulating core layer.

At least a part of the insulating auxiliary members may be disposed between a center line of the insulating core layer and the first surface.

The insulating core layer may have a concave portion disposed in the first surface, and the insulating auxiliary member may be disposed in the concave portion.

The number of the concave portions may be two or more, and the concave portions may have a grid structure.

The concave portion may have a trench structure.

The number of the concave portions may be two or more, and the concave portions may have parts intersecting with one another.

A CTE of the first substrate portion and a CTE of the second substrate portion may be different from each other.

The CTE of the first substrate portion may be smaller than the CTE of the second substrate portion.

The first substrate portion may further include a first connection pad which is disposed on a surface of the first insulating layer, and the second substrate portion further may include a second connection pad which is disposed on a surface of the second insulating layer.

An inorganic filler content of the first insulating layer may be higher than an inorganic filler content of the second insulating layer.

The circuit board may further include a first protective layer that is disposed on the first insulating layer, and has a first opening overlapping the first connection pad, and a second protective layer that is disposed on the second insulating layer, and has a second opening overlapping the second connection pad.

The insulating auxiliary member may be disposed only in one of the first surface and the second surface of the insulating core layer.

The insulating auxiliary member may include a plurality of portions spaced apart from each other.

A difference in CTE between parts, disposed in a first region of the circuit board, of the first substrate portion and the second substrate portion overlapping each other in a direction perpendicular to the first surface may be greater than a difference in CTE between parts, disposed in a second region of the circuit board, of the first substrate portion and the second substrate portion overlapping each other in the direction perpendicular to the first surface. Among the first region and second region of the circuit board, the insulating auxiliary member may be disposed only in the first region.

Another embodiment provides a method of fabricating a circuit board including forming a concave portion in a first surface of an insulating core layer having the first surface and a second surface opposing each other, disposing an insulating auxiliary members having a CTE different from that of the insulating core layer, in the concave portion, forming a first circuit wiring and a first insulating layer on the first surface of the insulating core layer, and forming second circuit wiring and a second insulating layer on the second surface of the insulating core layer.

The disposing of the insulating auxiliary member may include disposing an insulating material having a CTE higher than that of the insulating core layer, in the concave portion.

The forming of the concave portion in the first surface of the insulating core layer may include perforating the insulating core layer to a depth smaller than or equal to half a thickness of the insulating core layer in a first direction perpendicular to the first surface by a laser.

The forming of the concave portion in the first surface of the insulating core layer may include forming a through-hole in a first sub insulating core layer, and bonding the first sub insulating core layer to a second sub insulating core layer.

The bonding of the first sub insulating core layer to the second sub insulating core layer may include disposing an adhesive layer between the first sub insulating core layer and the second sub insulating core layer.

According to at least one of the embodiments, it is possible to alleviate the imbalance in coefficient of thermal expansion between the upper part and lower part of the circuit board relative to the center line, thereby coping with a warpage phenomenon.

However, the effects of the embodiments are not limited to the above-described effects, and it is apparent that they can be variously expanded without departing from the spirit and scope of the present invention.

### BRIEF DESCRIPTION OF THE DRAWINGS

FIG. 1 is a cross-sectional view illustrating a circuit board according to an embodiment.

FIG. 2A to FIG. 2D are plan views illustrating various examples in which insulating auxiliary members shown in FIG. 1 are disposed in an insulating core layer.

FIG. 3 is a cross-sectional view illustrating a modification of the circuit board shown in FIG. 1.

FIG. 4 to FIG. 11 are cross-sectional views illustrating a method of fabricating a circuit board according to an embodiment.

### DETAILED DESCRIPTION OF THE EMBODIMENTS

In the following detailed description, only certain embodiments of the present disclosure have been shown and described, simply by way of illustration. The present disclosure can be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto. In the drawings, the sizes and thicknesses of layers, films, panels, regions, etc., are exaggerated for clarity. Further, in the drawings, for understanding and ease of description, the thickness of some layers and areas is exaggerated.

The accompanying drawings are provided for helping to easily understand embodiments disclosed in the present specification, and the technical spirit disclosed in the present specification is not limited by the accompanying drawings, and it will be appreciated that the present disclosure includes all of the modifications, equivalent matters, and substitutes included in the spirit and the technical scope of the present disclosure.

Terms including an ordinary number, such as first and second, are used for describing various constituent elements, but the constituent elements are not limited by the terms. The terms are used only to discriminate one constituent element from another constituent element.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In the present application, it will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance. Accordingly, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

Further, throughout the specification, when it is referred to as “connected”, this does not only mean that two or more constituent elements are directly connected, but may mean that two or more constituent elements are indirectly connected through another constituent element, are physically connected, electrically connected, or are integrated even though two or more constituent elements are referred as different names depending on a location and a function.

Throughout this specification, boards have a structure wide in a plan view and thin in a cross-sectional view, and the ‘plane direction of a board’ may refer to a direction parallel with a wide and flat surface of the board, and the ‘thickness direction of a board’ may refer to a direction perpendicular to a wide and flat surface of the board.

Hereinafter, various embodiments and modifications will be described in detail with reference to the drawings.

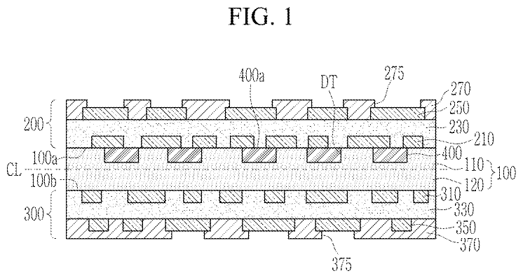

FIG. 1 is a cross-sectional view illustrating a circuit board according to an embodiment.

Referring to FIG. 1, the circuit board according to the present embodiment may include an insulating core layer 100, a first substrate portion 200 that is disposed on the insulating core layer 100, a second substrate portion 300 that is disposed below the insulating core layer 100, and insulating auxiliary members 400 that are disposed in the insulating core layer 100.

The insulating core layer 100 may have a preset area and thickness. The insulating core layer 100 may have a first surface 100a and a second surface 100b facing each other. The insulating core layer 100 may have a structure that is wide in a plan view and is thin in a cross-sectional view. A direction perpendicular to the first surface 100a or the second surface 100b may refer to a direction perpendicular to a wide and flat surface of the insulating core layer 100.

The insulating core layer 100 may contain a thermosetting resin such as epoxy resin, polyimide, etc., and a thermoplastic resin such as polyethylene (PE), polycarbonate (PC), polyvinyl chloride (PVC), etc., and may contain a resin including a reinforcement material such as glass fiber or an inorganic filler, etc., together with the above-mentioned materials. For example, the insulating core layer 100 may contain prepreg, Ajinomoto build-up film (ABF), photo imageable dielectric (PID), a bismaleimide triazine (BT) resin, etc.

The insulating core layer 100 may include a first insulating core layer 110 that is disposed from a center line CL of the insulating core layer 100 to the first surface 100a, and a second insulating core layer 120 that is disposed from the center line CL to the second surface 100b. The insulating core layer 100 may have concave portions DT which are formed from the first surface 100a in some parts of the insulating core layer 100. The concave portions DT may be formed in the first insulating core layer 110. The depth of the concave portion DT that is measured in a first direction perpendicular to the first surface 100a may be smaller than or equal to half the thickness of the insulating core layer 100 that is measured in the first direction. In other words, the concave portion DT may be formed in the first insulating core layer 110, and may not extend into the second insulating core layer 120.

The first substrate portion 200 may be disposed on the first surface 100a of the insulating core layer 100. The first substrate portion 200 may include a first circuit wiring 210, a first insulating layer 230, a first connection pad 250, and a first protective layer 270.

The first circuit wiring 210 may be disposed on the first surface 100a of the insulating core layer 100. The first circuit wiring 210 may transmit electric signals. The first circuit wiring 210 may be arranged in various patterns. The first circuit wiring 210 may contain a conductive material such as copper (Cu), aluminum (Al), silver (Ag), tin (Sn), gold (Au), nickel (Ni), lead (Pb), titanium (Ti), or an alloy thereof.

In FIG. 1, it is shown that one wiring layer is disposed as the first circuit wiring 210 on the first surface 100a; however, the first circuit wiring 210 is not limited thereto, and may consist of multiple wiring layers. In other words, the first circuit wiring 210 may include a wiring layer on the first surface 100a, and one or more wiring layers which are disposed over the said wiring layer on the first surface 100a, which also falls within the scope of the present disclosure. The wiring layers may be connected to each other by via layers.

The first insulating layer 230 may be disposed on the first surface 100a of the insulating core layer 100. The first circuit wiring 210 may be embedded in the first insulating layer 230. The first insulating layer 230 may contain a thermosetting resin such as epoxy resin, polyimide, or the like, and a thermoplastic resin such as polyethylene (PE), polycarbonate (PC), polyvinyl chloride (PVC), or the like, etc. Also, the first insulating layer 230 may contain a resin including a reinforcement material such as glass fiber or an inorganic filler, etc. For example, the first insulating layer 230 may contain prepreg, Ajinomoto build-up film (ABF), photo imageable dielectric (PID), etc., but is not limited thereto.

The first connection pad 250 may be disposed on the first insulating layer 230. In other words, the first connection pad 250 may be disposed on a surface of the first insulating layer 230. The surface of the first insulating layer 230 may refer to a side of the first insulating layer 230 which is opposite the side on which the first insulating layer 230 contacts the first surface 100a. The first connection pads 250 may be arranged in various patterns on the first insulating layer 230. The first connection pad 250 may contain a conductive material such as copper (Cu), aluminum (Al), silver (Ag), tin (Sn), gold (Au), nickel (Ni), lead (Pb), titanium (Ti), or an alloy thereof.

Although not shown in the drawing, in the first insulating layer 230, vias may be formed so as to electrically connect the first circuit wiring 210 with the first connection pad 250. For example, the vias may contain copper (Cu), silver (Ag), palladium (Pd), aluminum (Al), nickel (Ni), titanium (Ti), gold (Au), platinum (Pt), an alloy thereof, etc. The vias may be formed of the same material as that of the first circuit wiring 210.

The first protective layer 270 may be disposed on the first insulating layer 230. The first protective layer 270 may contain an insulating material such as a solder resist. The first protective layer 270 may have a first opening 275 which overlap the first connection pad 250. In other words, the first connection pad 250 may be exposed to the outside by the first opening 275.

The second substrate portion 300 may be disposed on the second surface 100b of the insulating core layer 100. The second substrate portion 300 may include a second circuit wiring 310, a second insulating layer 330, a second connection pad 350, and a second protective layer 370.

The second circuit wiring 310 may be disposed on the second surface 100b of the insulating core layer 100. The second circuit wiring 310 may transmit electric signals. The second circuit wiring 310 may be arranged in various patterns. The second circuit wiring 310 may contain a conductive material such as copper (Cu), aluminum (Al), silver (Ag), tin (Sn), gold (Au), nickel (Ni), lead (Pb), titanium (Ti), or an alloy thereof.

In FIG. 1, it is shown that one wiring layer is disposed as the second circuit wiring 310 on the second surface 100b; however, the second circuit wiring 310 is not limited thereto, and may consist of multiple wiring layers. In other words, the second circuit wiring 310 may include a wiring layer on the second surface 100b, and one or more wiring layers which are disposed under the said wiring layer on the second surface 100b, which also falls within the scope of the present disclosure. The wiring layers may be connected to each other by via layers.

The second insulating layer 330 may be disposed below the insulating core layer 100. The second circuit wiring 310 may be embedded in the second insulating layer 330. The second insulating layer 330 may contain a thermosetting resin such as epoxy resin, polyimide, or the like, and a thermoplastic resin such as polyethylene (PE), polycarbonate (PC), polyvinyl chloride (PVC), or the like, etc. Also, the second insulating layer 330 may contain a resin including a reinforcement material such as glass fiber or an inorganic filler, etc. For example, the second insulating layer 330 may contain prepreg, Ajinomoto build-up film (ABF), photo imageable dielectric (PID), etc., but is not limited thereto.

The second connection pad 350 may be disposed below the second insulating layer 330. In other words, the second connection pads 350 may be disposed on the surface of the second insulating layer 330. The surface of the second insulating layer 330 may refer to a side of the second insulating layer 330 which is opposite the side on which the second insulating layer 300 contacts the second surface 100b. The second connection pads 350 may be arranged in various patterns below the second insulating layer 330. The second connection pads 350 may contain a conductive material such as copper (Cu), aluminum (Al), silver (Ag), tin (Sn), gold (Au), nickel (Ni), lead (Pb), titanium (Ti), or an alloy thereof.

Although not shown in the drawing, in the second insulating layer 330, vias may be formed so as to electrically connect the second circuit wiring 310 with the second connection pad 350. For example, the vias may contain copper (Cu), silver (Ag), palladium (Pd), aluminum (Al), nickel (Ni), titanium (Ti), gold (Au), platinum (Pt), an alloy thereof, etc. The vias may be formed of the same material as that of the second circuit wiring 310.

The second protective layer 370 may be disposed below the second insulating layer 330. The second protective layer 370 may contain an insulating material such as a solder resist. The second protective layer 370 may have a second openings 375 which overlap the second connection pad 350. In other words, the second connection pad 350 may be exposed to the outside by the second opening 375.

The first substrate portion 200 and the second substrate portion 300 may be different from each other in the coefficient of thermal expansion (CTE). The CTEs of the first substrate portion 200 and the second substrate portion 300 may be measured by a CTE measurement device such as a thermal mechanical analyzer (TMA), a dilatometer, etc. For example, the CTEs may be obtained by measuring the expanded or contracted lengths of the first substrate portion 200 and the second substrate portion 300 in the plane direction of the circuit board, i.e., in a direction parallel with a wide and flat surface of the circuit board by a CTE measurement device. Alternatively, the CTEs of the first substrate portion 200 and the second substrate portion 300 may be obtained by measuring the expanded or contracted length of each of the first circuit wiring 210, the second circuit wiring 310, the first insulating layer 230, the second insulating layer 330, the first connection pad 250, the second connection pad 350, the first protective layer 270, and the second protective layer 370 of the first substrate portion and the second substrate portion in the plane direction of the circuit board. The CTEs of the first substrate portion 200 and the second substrate portion 300 are weighted averages of the CTEs of the individual components. In other words, the CTE of the first substrate portion 200 may be the weighted average of the CTEs of the first circuit wiring 210, the first insulating layer 230, the first connection pad 250, and the first protective layer 270, and the CTE of the second substrate portion 300 may be the weighted average of the CTEs of the second circuit wiring 310, the second insulating layer 330, the second connection pad 350, and the second protective layer 370. Depending on the configurations of the first and second substrate portions 200 and 300, the weighted average of the CTE of the first circuit wiring 210 and the CTE of the first insulating layer 230 may be used as the CTE of the first substrate portion 200, and the weighted average of the CTE of the second circuit wiring 310 and the CTE of the second insulating layer 330 may be used as the CTE of the second substrate portion 300. In order to measure the CTEs of the first substrate portion 200 and the second substrate portion 300, samples may be used, and displacements may be measured by expanding or contracting the samples.

The difference in CTE between the first substrate portion 200 and the second substrate portion 300 may be caused by various factors including the materials differences in circuit wiring, or the contents of inorganic fillers in the insulating layers. As an example, the area of the second circuit wiring 310 may be smaller than that of the first circuit wiring 210, whereby the CTE of the second substrate portion 300 may be larger than that of the first substrate portion 200. In this case, the number of wiring layers constituting the second circuit wiring 310 may be larger than the number of wiring layers constituting the first circuit wiring 210, whereby the area of the second circuit wiring 310 may be larger than that of the first circuit wiring 210. As another example, the content of an inorganic filler in the first insulating layer 230 may be higher than the content of an inorganic filler in the second insulating layer 330, whereby the CTE of the first substrate portion 200 may be smaller than the CTE of the second substrate portion 300.

At least some parts of the insulating auxiliary members 400 may be disposed in the insulating core layer 100. The insulating auxiliary members 400 may include parts disposed in the first insulating core layer 110. In other words, the insulating auxiliary members 400 may include parts disposed between the center line CL of the insulating core layer 100 and the first surface 100a.

The insulating auxiliary member 400 may be disposed in the concave portion DT of the insulating core layer 100. The upper surfaces 400a of the insulating auxiliary members 400 may be formed approximately at a level with the first surface 100a, but is not limited thereto. The upper surfaces 400a of the insulating auxiliary members 400 or a part including the upper surfaces 400a may be exposed from the insulating core layer 100, and the first substrate portion 200 may cover the exposed parts.

The insulating auxiliary members 400 may contain an insulating material, and may be formed of a material different from that of the insulating core layer 100. The insulating auxiliary members 400 and the insulating core layer 100 may be different from each other in the coefficient of thermal expansion (CTE).

For example, the insulating auxiliary members 400 may contain an insulating resin material having a CTE higher than the CTE of the insulating core layer 100. Accordingly, a CTE formed by the insulating auxiliary member 400 and the first insulating core layer 110 together may be higher than the CTE formed by the second insulating core layer 120 alone. In this case, the CTE formed by the insulating auxiliary member 400 and the first insulating core layer 100 together may be a weighted average of the CTE of the insulating auxiliary member 400 and the CTE of the first insulating core layer 110. The insulating auxiliary members 400 may be arranged over the entire circuit board in a plan view.

The insulating auxiliary members 400 can compensate the imbalance in CTE between the first substrate portion 200 and the second substrate portion 300. For example, when the CTE of the second substrate portion 300 is higher than the CTE of the first substrate portion 200, and therefore there is a risk of warpage due to the imbalance in CTE, the insulating auxiliary members 400 having a CTE higher than the CTE of the insulating core layer 100 may be disposed on the first insulating core layer 110, whereby it is possible to eliminate or alleviate the imbalance in CTE. In other words, when the CTE of the first substrate portion 200 is lower than the CTE of the second substrate portion 300, the insulating auxiliary members 400 having a CTE higher than the CTE of the insulating core layer 100 may be disposed on the first insulating core layer 110, such that the CTEs of the upper part and the lower part relative to the center line CL become equal or similar to each other.

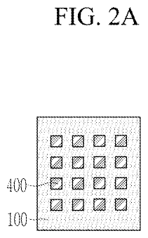

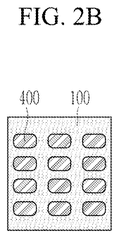

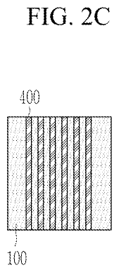

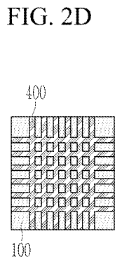

FIG. 2A to FIG. 2D are plan views illustrating various examples in which insulating auxiliary members shown in FIG. 1 are disposed in the insulating core layer.

The insulating auxiliary members 400 may have a preset area and thickness. The insulating auxiliary members 400 may have a plate structure, and may be circular, elliptical, or polygonal in a plan view. Referring to FIG. 2A to FIG. 2D, the insulating auxiliary members 400 may be arranged so as to form a predetermined pattern. As an example, the insulating auxiliary members 400 may be arranged in a grid structure (see FIG. 2A and FIG. 2B). Alternatively, the insulating auxiliary members 400 may be formed in a trench structure, which is an elongated groove form (see FIG. 2C). The insulating auxiliary members 400 may have a trench structure and be arranged to intersect (see FIG. 2D). However, the arrangement of the insulating auxiliary members 400 is not limited to the structures shown in FIG. 2A to FIG. 2D, and the insulating auxiliary members 400 may be formed in various patterns.

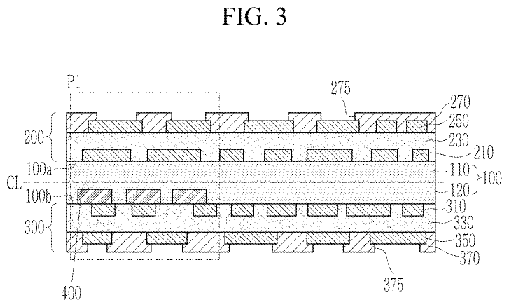

FIG. 3 is a cross-sectional view illustrating a modification of the circuit board shown in FIG. 1.

The circuit board shown in FIG. 3 has essentially a laminate structure, similarly to the circuit board shown in FIG. 1. In other words, the circuit board according to the modification includes an insulating core layer 100, a first substrate portion 200 that is disposed on the insulating core layer 100, a second substrate portion 300 that is disposed below the insulating core layer 100, and an insulating auxiliary members 400 that are disposed in the insulating core layer 100. The first substrate portion 200 may include a first circuit wiring 210, a first insulating layer 230, a first connection pad 250, and a first protective layer 270. The second substrate portion 300 may include a second circuit wiring 310, a second insulating layer 330, a second connection pad 350, and a second protective layer 370.

The insulating auxiliary members 400 may be disposed in some parts of the circuit board in a plan view. A preset imbalance in CTE between the first substrate portion 200 and the second substrate portion 300 may be calculated. When the difference in CTE between some parts of the first substrate portion 200 and the second substrate portion 300 is large, the insulating auxiliary members 400 may be arranged in the corresponding parts, whereby it is possible to prevent the occurrence of complex warpage such as saddle-shaped warpage. In order to calculate the CTEs of the first substrate portion 200 and the second substrate portion 300, a Gerber file or the like may be used.

For example, referring to FIG. 3, when the imbalance in CTE between parts of the first substrate portion 200 and the second substrate portion 300 overlapping each other in the first direction perpendicular to the first surface 100a in part P1 is large, the insulating auxiliary members 400 may be arranged in the second insulating core layer 120 in part P1, whereby it is possible to alleviate the imbalance in CTE.

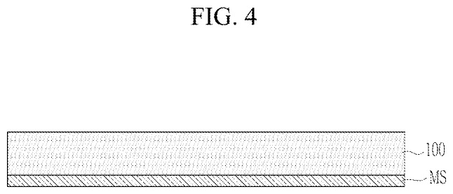

FIG. 4 to FIG. 11 are cross-sectional views illustrating a method of fabricating a circuit board according to an embodiment. Hereinafter, a method of fabricating a circuit board according to an embodiment will be described with reference to FIG. 4 to FIG. 11 in conjunction with FIG. 1 to FIG. 3.

Referring to FIG. 4, first, an insulating core layer 100 is prepared. For example, in order to prepare an insulating core layer 100, a copper clad laminate (CCL) which is prepreg with thin metal layers (MS) on either one side or both sides and is able to form the insulating core layer 100 may be used.

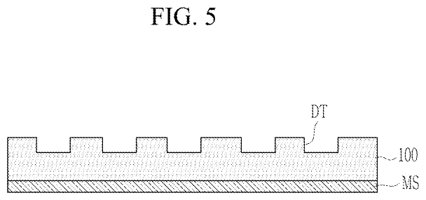

Referring to FIG. 5, the concave portion DT are formed in the insulating core layer 100. The concave portion DT may be formed in a first surface 100a. As an example, the concave portion DT may have a plate structure, and be formed in a circular, elliptical, or polygonal shape in a plan view. As another example, the concave portion DT may be formed in a trench structure.

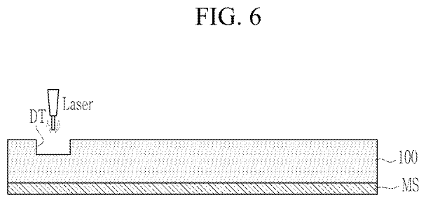

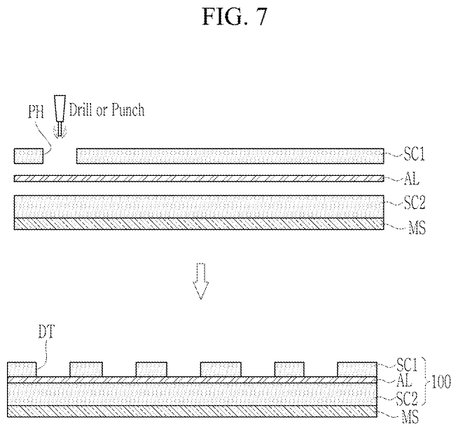

FIG. 6 and FIG. 7 are plan views illustrating a method of forming the concave portion DT of FIG. 5.

As shown in FIG. 6, the concave portion DT may be formed by perforating the insulating core layer 100 to a predetermined depth. As an example, the concave portion DT may be formed by a laser. The concave portion DT may be formed such that their depth which is measured in the first direction is smaller than or equal to half the thickness of the insulating core layer 100.

As another example, as shown in FIG. 7, in order to form the insulating core layer 100, a first sub insulating core layer SC1 and a second sub insulating core layer SC2 may be prepared. The thickness of the first sub insulating core layer SC1 may be smaller than or equal to the thickness of the second sub insulating core layer SC2. Through-holes PH may be formed so as to pass through the first sub insulating core layer SC1. In order to form the through-holes PH, a drill or a punch may be used. Subsequently, the first sub insulating core layer SC1 and the second sub insulating core layer SC2 are bonded. For the bonding, an adhesive layer AL may be disposed between the first sub insulating core layer SC1 and the second sub insulating core layer SC2, and the first sub insulating core layer SC1 and the second sub insulating core layer SC2 may be bonded by the adhesive layer AL, thereby forming the insulating core layer 100.

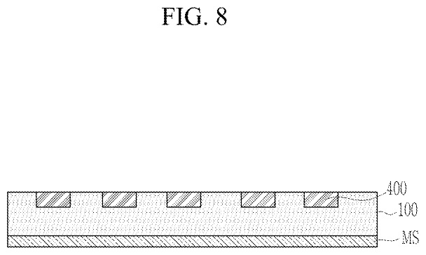

Referring to FIG. 8, insulating auxiliary members 400 are disposed in the concave portions DT. The insulating auxiliary members 400 may be formed in the concave portions DT, and may also protrude from the concave portions DT. The insulating auxiliary members 400 may be formed of an insulating material having a CTE higher than that of the insulating core layer 100. The insulating auxiliary members 400 may have various shapes and sizes and be arranged in various patterns, depending on the difference in CTE between the first substrate portion 200 and the second substrate portion 300. In the embodiment it is shown that the insulating auxiliary members 400 are formed at a level with the first surface 100a; however, the insulating auxiliary members are not limited thereto. For example, the insulating auxiliary members 400 may be formed by filling the concave portions DT with an insulating material having a CTE higher than that of the insulating core layer 100.

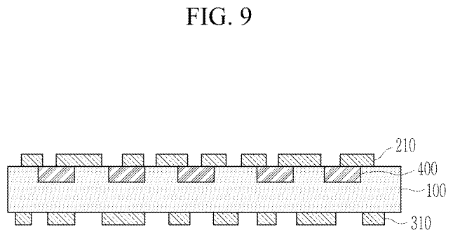

Referring to FIG. 9, the first circuit wiring 210 is formed on the first surface 100a of the insulating core layer 100, and the second circuit wiring 310 is formed on the second surface 100b. On the insulating core layer 100, a plating resist may be stacked, and exposing and developing may be performed so as to remove only parts where the first circuit wiring 210 is to be formed, such that a plating resist pattern is formed. Then, a conductive metal may be stacked on the parts where there is no plating resist pattern. In this way, the first circuit wiring 210 may be formed. In a similar manner, the second circuit wiring 310 may be formed.

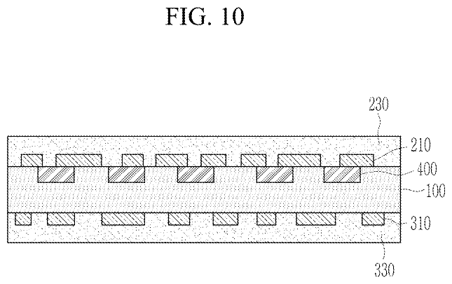

Referring to FIG. 10, on the first surface 100a of the insulating core layer 100, the first insulating layer 230 is formed so as to cover the first circuit wiring 210, and on the second surface 100b, the second insulating layer 330 is formed so as to cover the second circuit wiring 310.

Although not shown in the drawings, in the first insulating layer 230 and the second insulating layer 330, vias may be formed so as to expose the first circuit wiring 210 and the second circuit wiring 310, respectively.

In FIG. 9 and FIG. 10, it is shown that as each of the first circuit wiring 210, the first insulating layer 230, the second circuit wiring 310, and the second insulating layer 330, one layer is stacked; however, they are not limited thereto. In other words, on a stacked insulating layer, another circuit wiring layer and another insulating layer may be stacked, and such stacking may be repeatedly performed. Also, stacking may be performed such that the number of circuit wiring layers which are included in the first circuit wiring 210 is different from the number of circuit wiring layers which are included in the second circuit wiring 310.

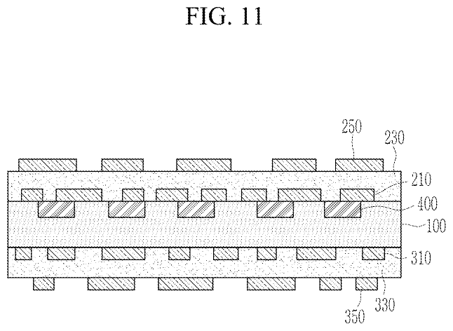

Subsequently, as shown in FIG. 11, on the first insulating layer 230, the first connection pads 250 are formed, and on the second insulating layer 330, the second connection pads 350 are formed. The first and second connection pads 250 and 350 may be formed in a manner similar to the above-mentioned manner in which the first and second circuit wiring 210 and 310 are formed.

Subsequently, referring to FIG. 1 again, on the first insulating layer 230, the first protective layer 270 may be formed, and below the second insulating layer 330, the second protective layer 370 may be formed.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A circuit board comprising:
an insulating core layer that has a first surface and a second surface opposing each other;
an insulating auxiliary member of which at least a part is disposed in the insulating core layer and which has a coefficient of thermal expansion (CTE) different from that of the insulating core layer;
a first substrate portion that includes a first insulating layer which is disposed on the first surface, and a first circuit wiring which is embedded in the first insulating layer; and
a second substrate portion that includes a second insulating layer which is disposed on the second surface, and a second circuit wiring which is embedded in the second insulating layer.

2. The circuit board of claim 1, wherein
the insulating auxiliary member has the CTE higher than that of the insulating core layer.

3. The circuit board of claim 1, wherein
at least a part of the insulating auxiliary member is disposed between a center line of the insulating core layer and the first surface.

4. The circuit board of claim 3, wherein
the insulating core layer has a concave portion disposed in the first surface, and
the insulating auxiliary member is disposed in the concave portion.

5. The circuit board of claim 4, wherein
the number of the concave portions is two or more, and
the concave portions have a grid structure.

6. The circuit board of claim 4, wherein
the concave portion has a trench structure.

7. The circuit board of claim 6, wherein
the number of the concave portions is two or more, and
the concave portions have parts intersecting with one another.

8. The circuit board of claim 1, wherein
a CTE of the first substrate portion and a CTE of the second substrate portion are different from each other.

9. The circuit board of claim 8, wherein
the CTE of the first substrate portion is smaller than the CTE of the second substrate portion.

10. The circuit board of claim 1, wherein
the first substrate portion further includes a first connection pad which is disposed on a surface of the first insulating layer, and
the second substrate portion further includes a second connection pad which is disposed on a surface of the second insulating layer.

11. The circuit board of claim 1, wherein
an inorganic filler content of the first insulating layer is higher than an inorganic filler content of the second insulating layer.

12. The circuit board of claim 10, further comprising:
a first protective layer that is disposed on the first insulating layer, and has a first opening overlapping the first connection pad; and
a second protective layer that is disposed on the second insulating layer, and has a second openings overlapping the second connection pad.

13. The circuit board of claim 1, wherein
the insulating auxiliary member is disposed only in one of the first surface and the second surface of the insulating core layer.

14. The circuit board of claim 1, wherein
the insulating auxiliary member includes a plurality of portions spaced apart from each other.

15. The circuit board of claim 1, wherein
a difference in CTE between parts, disposed in a first region of the circuit board, of the first substrate portion and the second substrate portion overlapping each other in a direction perpendicular to the first surface is greater than a difference in CTE between parts, disposed in a second region of the circuit board, of the first substrate portion and the second substrate portion overlapping each other in the direction perpendicular to the first surface, and
among the first region and second region of the circuit board, the insulating auxiliary member is disposed only in the first region.

16. A method of fabricating a circuit board, the method comprising:
forming a concave portion in a first surface of an insulating core layer having the first surface and a second surface opposing each other;
disposing an insulating auxiliary member having a CTE different from that of the insulating core layer, in the concave portion;
forming a first circuit wiring and a first insulating layer on the first surface of the insulating core layer; and
forming a second circuit wiring and a second insulating layer on the second surface of the insulating core layer.

17. The method of fabricating a circuit board according to claim 16, wherein
the disposing of the insulating auxiliary member includes disposing an insulating material having a CTE higher than that of the insulating core layer, in the concave portion.

18. The method of fabricating a circuit board according to claim 16, wherein
the forming of the concave portion in the first surface of the insulating core layer includes perforating the insulating core layer to a depth smaller than or equal to half a thickness of the insulating core layer in a first direction perpendicular to the first surface by a laser.

19. The method of fabricating a circuit board according to claim 16, wherein
the forming of the concave portion in the first surface of the insulating core layer includes the following:
forming a through-hole in a first sub insulating core layer; and
bonding the first sub insulating core layer to a second sub insulating core layer.

20. The method of fabricating a circuit board according to claim 19, wherein
the bonding of the first sub insulating core layer to the second sub insulating core layer includes disposing an adhesive layer between the first sub insulating core layer and the second sub insulating core layer.
